(19) United States
(12) Patent Application Publication
(10) Pub. No.: US 2026/0013257 A1
(43) Pub. Date: Jan. 8, 2026

(54) SOLID-STATE IMAGING DEVICE

(71) Applicant: Samsung Electronics Co., Ltd., Suwon-si (KR)

(72) Inventor: Natsuki FUKUDA, Yokohama (JP)

(73) Assignee: Samsung Electronics Co., Ltd., Suwon-si (KR)

(21) Appl. No.: 19/251,167

(22) Filed: Jun. 26, 2025

(30) Foreign Application Priority Data
Jul. 5, 2024 (JP) 2024-108656

(51) Int. Cl. H10F 39/00; H10F 39/18

(52) U.S. Cl. CPC H10F 39/807; H10F 39/182

(57) ABSTRACT

A solid-state imaging device includes a two-dimensional array including a plurality of pixels on a chip substrate. Each pixel includes a photoelectric converter that detects phase difference and includes a first photoelectric converter and a second photoelectric converter. Each pixel includes a first separation wall configured to surround a periphery of the photoelectric converter and a second separation wall between the first photoelectric converter and the second photoelectric converter. The second separation wall includes a first portion in a center portion of a pixel pitch, and a second portion adjacent to the first portion. A vertical position of a first end portion of the first portion is lower than a vertical position of a second end portion of the second portion. Light is incident on the first end portion and the second end portion of the solid-state imaging device in a Z-axis direction.

### CROSS-REFERENCE TO RELATED APPLICATION

This U.S. non-provisional application claims the benefit of Japanese Patent Application No. 2024-108656, filed on Jul. 5, 2024, in the Japanese Patent Office, the disclosure of which is incorporated herein by reference in its entirety.

### BACKGROUND

An auto-focus method of automatic focusing may include an on-sensor phase difference detection method in which focusing is performed by using two photoelectric converters to utilize the phase difference of the object image and measure the distance between the object and the imaging lens to focus.

Some solid-state imaging devices may include a separation wall between the two photoelectric converters divided in a pixel. Referring to FIG. 16, the solid-state imaging device may prevent, reduce, or limit the occurrence of cross-talk, but light that may be incident on an end portion of the separation wall may be reflected from the incident side to the on-chip lens side of the pixel relatively easily.

Some other solid-state imaging devices may have a structure in which a separation structure or wall is not formed at the center portion of each pixel. Accordingly, these solid-state imaging devices may prevent, reduce, or limit reflection of light that is incident on an end portion of the separation wall. However, referring to FIG. 17, cross-talk may occur in these solid-state imaging devices between the adjacent photoelectric converters in the pixel and phase difference detection precision is deteriorated or reduced.

### SUMMARY

Example embodiments of the inventive concepts relate to a solid-state imaging device including pixels configured to perform a phase difference detection operation.

Example embodiments of the inventive concepts provide a solid-state imaging device configured to improve the phase difference detection precision by suppressing or reducing or limiting cross-talk between photoelectric converters in each pixel and/or by suppressing or reducing or limiting reflection of incident light from the separation wall.

According to some example embodiments, a solid-state imaging device includes a two-dimensional pixel array including a plurality of pixels on a chip substrate. Each pixel of the plurality of pixels comprises a photoelectric converter configured to detect a phase difference and including a first photoelectric converter and a second photoelectric converter. Each pixel of the plurality of pixels comprises a first separation wall configured to surround a periphery of the photoelectric converter and a second separation wall between the first photoelectric converter and the second photoelectric converter. The second separation wall comprises a first portion in a center portion of a pixel pitch, and a second portion adjacent to the first portion. A vertical position of a first end portion of the first portion is lower than a vertical position of a second end portion of the second portion. Light is incident on the first end portion and the second end portion of the solid-state imaging device in a Z-axis direction.

According to some example embodiments, a solid-state imaging device includes a two-dimensional array of a plurality of pixels. Each pixel of the plurality of pixels comprises a separation wall configured to separate a photoelectric converter included in the pixel. The separation wall includes a first portion in a center portion of a pixel pitch and two second portions on both sides of the first portion in a second direction. End portions of the two second portions are configured to contact a first surface and an end portion of the first portion is apart from the first surface. The first surface is a surface of the photoelectric converter on which light is incident.

According to some example embodiments, a solid-state imaging device includes a plurality of pixels on a chip substrate. Each pixel of the plurality of pixels includes a first photoelectric converter and a second photoelectric converter inside the chip substrate, a separation wall between the first photoelectric converter and the second photoelectric converter, a color filter on the first photoelectric converter and the second photoelectric converter, and an on-chip lens on the color filter. The separation wall further comprises a groove portion between the first photoelectric converter and the second photoelectric converter, and the groove portion includes a same material as the first photoelectric converter and the second photoelectric converter.

According to some example embodiments, a method of operating a solid-state imaging device includes scanning in a first direction, using a vertical driving circuit, each pixel of a plurality of pixels of the solid-state imaging device, outputting, using a horizontal driving circuit, a scanning pulse in a second direction, and generating, using a column signal processing circuit, an imaging signal by processing a pixel signal output by each pixel of the plurality of pixels. The solid-state imaging device includes a two-dimensional pixel array including a plurality of pixels on a chip substrate. Each pixel of the plurality of pixels includes a photoelectric converter configured to detect a phase difference and including a first photoelectric converter and a second photoelectric converter. Each pixel of the plurality of pixels includes a first separation wall configured to surround a periphery of the photoelectric converter and a second separation wall between the first photoelectric converter and the second photoelectric converter. The second separation wall includes a first portion in a center portion of a pixel pitch, and a second portion adjacent to the first portion, A vertical position of a first end portion of the first portion is lower than a vertical position of a second end portion of the second portion. Light is incident on the first end portion and the second end portion of the solid-state imaging device in a Z-axis direction. According to some example embodiments, the second separation wall includes a groove portion, the groove portion being concave from a first surface of the photoelectric converter toward the first end portion of the first portion, and the groove portion includes a same material as the photoelectric converter. According to some example embodiments, the first photoelectric converter is at a center side of the chip substrate, the second photoelectric converter is on an outer periphery side of the chip substrate, wherein a distance between the first end portion of the second separation wall and a first surface is equal to or less than pixel pitch/tan θ with respect to an incident angle θ of light incident on the second photoelectric converter, and the first surface is a surface of the photoelectric converter on which the light is incident. According to some example embodiments, the plurality of pixels comprises a red color pixel, a green color pixel, and a blue color pixel. At least one of (1) a first distance (L_{R}) between the first end portion of the first portion of the red color pixel and a first surface of the photoelectric converter, (2) a second distance (L_{G}) between the first end portion of the first portion of the green color pixel and the first surface of the photoelectric converter, and (3) a third distance (L_{B}) between the first end portion of the first portion of the blue color pixel and the first surface of the photoelectric converter is different from other of the first distance, the second distance, and the third distance.

### BRIEF DESCRIPTION OF THE DRAWINGS

Example embodiments of the inventive concepts will be more clearly understood from the following detailed description taken in conjunction with the accompanying drawings in which:

FIG. 1A is a block diagram of a solid-state imaging device according to some example embodiments.

FIG. 1B is an enlarged cross-sectional view of a portion of the solid-state imaging device taken in a horizontal direction (taken in an XY plane), according to some example embodiments.

FIG. 2A is a schematic cross-sectional view of the solid-state device taken along line A-A illustrated in FIG. 1B.

FIG. 2B is a schematic cross-sectional view of the solid-state device taken along line B-B illustrated in FIG. 1B.

FIG. 3 is a diagram of conditions for defining a height of a first portion of a second separation wall, according to some example embodiments.

FIG. 4 is a diagram of relationships between a first distance (L_{R}) of a red color pixel, a second distance (L_{G}) of a green color pixel, and a third distance (L_{B}) of a blue color, according to some example embodiments.

FIG. 5 is a diagram of an example of an absorption rate of incident light with respect to a light path length in a photoelectric converter including silicon (Si), according to some example embodiments.

FIG. 6A is a schematic cross-sectional view of a pixel arranged on a center side of a solid-state imaging device, according to some example embodiments.

FIG. 6B is a schematic cross-sectional view of a pixel arranged on an outer periphery side of a solid-state imaging device, according to some example embodiments.

FIG. 7 is an enlarged cross-sectional view of a portion of a solid-state imaging device taken in a horizontal direction, according to some example embodiments.

FIG. 8A is a schematic cross-sectional view of a solid-state device taken along line C-C illustrated in FIG. 7.

FIG. 8B is a schematic cross-sectional view of a solid-state device having a different shape taken along line C-C illustrated in FIG. 7.

FIG. 8C is a schematic cross-sectional view of a solid-state device having a different shape taken along line C-C illustrated in FIG. 7.

FIG. 8D is a diagram illustrating an example of absorption distribution of incident light of a pixel in the solid-state imaging device illustrated in FIG. 8A.

FIG. 9 is an enlarged cross-sectional view of a portion of a solid-state imaging device taken in a horizontal direction, according to some example embodiments.

FIG. 10A is a schematic cross-sectional view of a solid-state imaging device taken along line D1-D1 illustrated in FIG. 9, and FIG. 10B is a schematic cross-sectional view of a solid-state imaging device taken along line D2-D2 illustrated in FIG. 9.

FIG. 11 is an enlarged cross-sectional view of a portion of a solid-state imaging device taken in a horizontal direction, according to some example embodiments.

FIG. 12A is a schematic cross-sectional view of a solid-state imaging device taken along line E1-E1 illustrated in FIG. 11, and FIG. 12B is a schematic cross-sectional view of a solid-state imaging device taken along line E2-E2 illustrated in FIG. 11.

FIG. 13 is an enlarged cross-sectional view of a portion of a solid-state imaging device taken in a horizontal direction, according to some example embodiments.

FIG. 14A is a schematic cross-sectional view of the solid-state imaging device taken along line F-F illustrated in FIG. 13.

FIG. 14B is a schematic cross-sectional view of a solid-state imaging device having a different shape taken along line F-F illustrated in FIG. 13.

FIG. 14C is a schematic cross-sectional view of a solid-state imaging device having a different shape taken along line G-G illustrated in FIG. 13.

FIG. 14D is a schematic cross-sectional view of a solid-state imaging device having a different shape taken along line G-G illustrated in FIG. 13.

FIG. 15 is a partially enlarged cross-sectional view of a portion of a solid-state imaging device in which a photoelectric converter is partitioned into four portions on a second separation wall in a horizontal direction, according to some example embodiments.

FIG. 16 is a conceptual diagram illustrating reflection of light in a solid-state imaging device according to a comparative example.

FIG. 17 is a conceptual diagram illustrating cross-talk in a solid-state imaging device according to a comparative example.

### DETAILED DESCRIPTION OF EXAMPLE EMBODIMENTS

Hereinafter, example embodiments of the inventive concepts will be described in detail with reference to the accompanying drawings. In the drawings below, like reference numerals in the drawings denote like components, and sizes of components in the drawings are exaggerated for clarity and convenience of description. On the other hand, embodiments described below are only examples, and various changes from the embodiments is possible.

Hereinafter, the term “on” or “above” may include not only directly above in contact but directly above without contact. Similarly, the term “under” or “below” may include not only directly under in contact but directly under without contact.

Singular expressions may include plural expressions unless they are explicitly specified in context. In addition, when a portion “includes”, “equipped”, or “has” a component, it may mean that the portion may include other components rather than excluding other components unless otherwise stated to the contrary.

For operations constituting a method, operations may be performed in an appropriate order, unless an explicit order or reverse order is specified. The embodiment is not necessarily limited to the described order of the operations. The use of all examples or example terms is simply for describing a technical idea of the inventive concept, and the scope of the inventive concept is not limited by these examples or example terms unless limited by the claims.

In addition, in the following description, when descriptions are provided with ordinal numerals, such as “first” and “second”, unless specifically stated, they are only for convenience, and do not specify any order.

Hereinafter, a configuration of a solid-state imaging device 1 according to some example embodiments is described.

For convenience of description, an XYZ orthogonal coordinate system may be set in the solid-state imaging device 1. A direction in parallel with an X-axis on a certain surface may be defined as an X-axis direction. A direction in parallel with a Y-axis orthogonal (or perpendicular) to the X-axis on the certain surface may be defined as a Y-axis direction. A direction in parallel with the Z-axis orthogonal to each of the X-axis and Y-axis may be defined as the Z-axis direction. In the inventive concept, the certain surface may be in parallel with a horizontal plane on an XY plane, and the Z-axis may be defined as a vertical direction orthogonal to the certain surface and as an axis in a thickness direction of the solid-state imaging device 1.

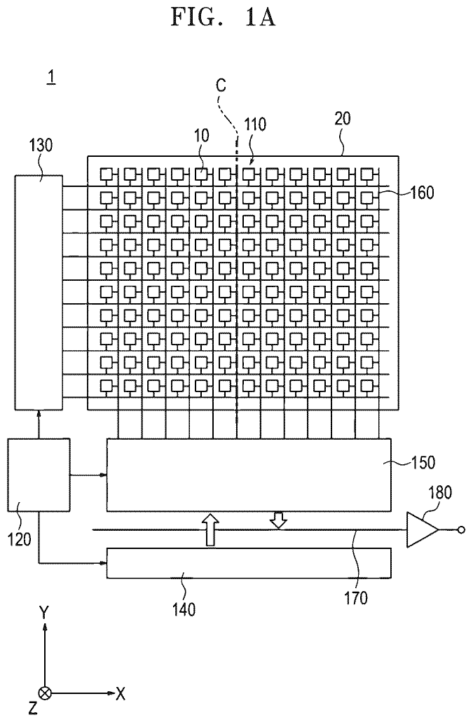

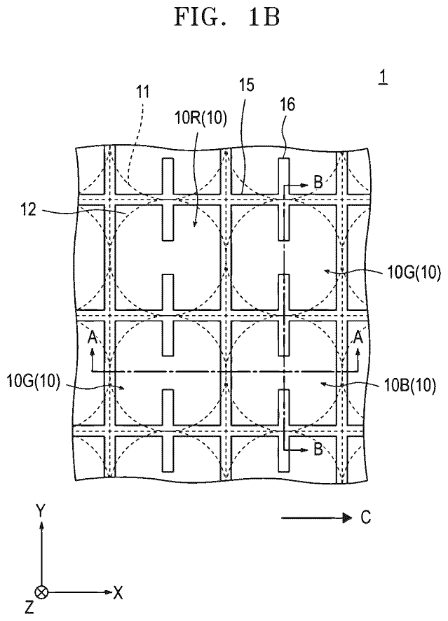

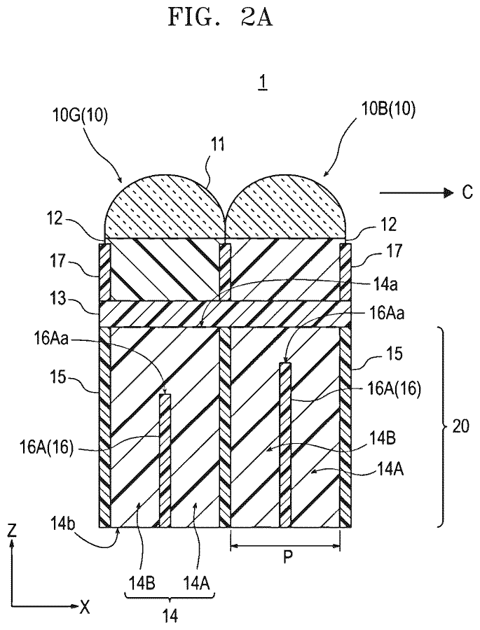

FIG. 1A is a block diagram of the solid-state imaging device 1 according to some example embodiments. The solid-state imaging device 1 may include a pixel 10 and a chip substrate 20. The solid-state imaging device 1 may include a complementary metal-oxide semiconductor (CMOS) image sensor.

Referring to FIG. 1A, the solid-state imaging device 1 may include a pixel array 110 including a plurality of pixels 10 outputting pixel signals, a control circuit 120 generating an operation signal for operating each component of the solid-state imaging device 1, a vertical driving circuit 130 capable of scanning each pixel 10 in a vertical direction (the Y-axis direction in the drawing) and controlling an output of a pixel signal according to the reception amount of each pixel 10, a horizontal driving circuit 140 outputting a scanning pulse in the horizontal direction (the X-axis direction in the drawing), a column signal processing circuit 150 generating an imaging signal by processing the pixel signal output by each pixel 10, a vertical signal line 160 transmitting the pixel signal generated by each pixel 10 to the column signal processing circuit 150, a horizontal signal line 170 outputting the imaging signal from the column signal processing circuit 150, and an output circuit 180 processing the imaging signal received via the horizontal signal line 170 and outputting the received imaging signal after the processing.

The solid-state imaging device 1, in addition to the pixel 10, may include other components generally known in the technical field of the solid-state imaging device, and a description of these components is omitted herein for the sake of brevity.

FIG. 1B illustrates an enlarged plan view of a portion of the solid-state imaging device 1 in the horizontal direction (taken in an XY plane). Referring to FIG. 1B, the solid-state imaging device 1 may include the plurality of pixels 10 including a plurality of red color pixels 10R, a plurality of green color pixels 10G, and a plurality of blue color pixels 10B. The plurality of pixels 10 may constitute the pixel array 110 arranged in a two-dimensional form (for example, in a matrix form) on the chip substrate 20.

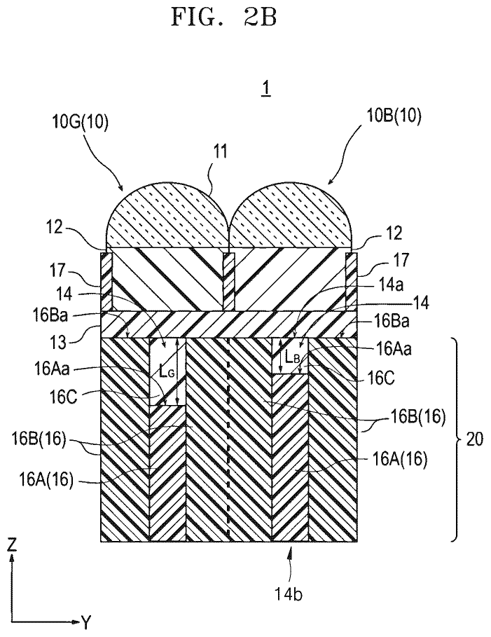

FIG. 2A is a schematic cross-sectional view of the solid-state imaging device 1 taken along line A-A illustrated in FIG. 1B. FIG. 2B is a schematic cross-sectional view of the solid-state imaging device 1 taken along line B-B illustrated in FIG. 1B.

Referring to FIGS. 2A and 2B, the pixel 10 may include an on-chip lens 11, a color filter 12, an anti-reflection layer 13, a photoelectric converter 14, a first separation wall 15, a second separation wall 16, and a grid pattern 17 in order from the incident surface of light.

The chip substrate 20 may include silicon or the like, and the plurality of pixels 10 may be formed on the chip substrate 20. The chip substrate 20 may include a pixel transistor, a wiring layer, or the like, on an opposite side of the incident surface of light, and may output the pixel signal obtained by converting the light that has been received by the photoelectric converter 14 into an electrical signal.

The pixel 10 may have a structure in which the photoelectric converter 14 is divided into multiple parts, and the auto-focusing may be implemented by calculating a deviation of the focus from the phase difference of the upper surface of the image obtained by the plurality of pixels 10. In an imaging device equipped with the solid-state imaging device 1, an auto-focusing device may be omitted, and instead the imaging device may focus on the object based on the phase difference of light incident on the pixel 10.

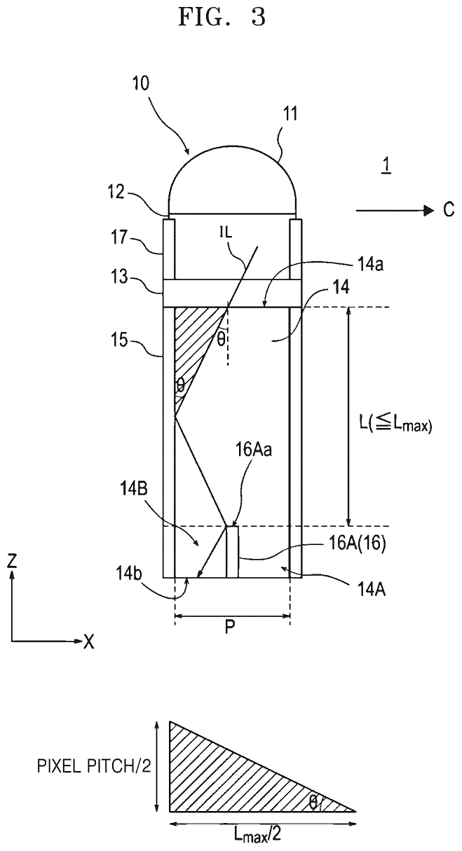

The on-chip lens 11 may be formed on the color filter 12. The on-chip lens 11 may be arranged to correspond to a pixel in units of the pixel 10. For example, the on-chip lens 11 may be arranged two-dimensionally (for example, in a matrix form) on a plane. The on-chip lens 11 may have a convex shape and a certain or given curvature radius so that incident light IL (refer to FIG. 3) is condensed on the photoelectric converter 14. The on-chip lens 11 may have light transmittance of about 90% or more with respect to light in a visible light range. The on-chip lens 11 may be formed by using, for example, a styrene resin, an acrylic resin, a styrene acrylic copolymer resin, a siloxane resin, or the like.

The color filter 12 may be formed on the anti-reflection layer 13. The color filter 12 may be arranged two-dimensionally (for example, in a matrix form) to correspond to each unit pixel. The color filter 12 may include various color filters in each unit pixel. For example, the color filter 12 may be arranged in a Bayer pattern including a red color filter, a green color filter, and a blue color filter. However, this is an example, and the color filter 12 may also include a yellow color filter, a magenta color filter, and a cyan color filter, and may also further include a white filter.

The anti-reflection layer 13 may prevent or limit incident light (refer to IL in FIG. 3) passing through the color filter 12 from being reflected or scattered to the side surface. The anti-reflection layer 13 may include at least one of silicon oxide, silicon nitride, silicon oxynitride, aluminum oxide, hafnium oxide, and a combination thereof. According to some example embodiments, the material of the anti-reflection layer 13 is not limited thereto, and any user desired material can be used as long as the material used results in an anti-reflection effect in the pixel 10. In addition, as the anti-reflection layer 13, a light-blocking layer including a metal layer such as aluminum (Al) may also be included.

The grid pattern 17 may be formed on an upper portion of the anti-reflection layer 13. The grid pattern 17 may be formed in a grid form in a plan view, and may be arranged between a plurality of color filters 12 to partition each pixel 10. The grid pattern 17 may include a low refractive index material having a refractive index lower than that of silicon (Si). The grid pattern 17 may include, for example, at least one of silicon oxide, aluminum oxide, tantalum oxide, and a combination thereof, but is not limited thereto. The grid pattern 17 including a low refractive index material may improve the quality of the solid-state imaging device 1 by refracting or reflecting light obliquely incident on the solid-state imaging device 1.

The photoelectric converter 14 may include a first photoelectric converter 14A and a second photoelectric converter 14B. The photoelectric converter 14 may be surrounded by the first separation wall 15 and be separated between the adjacent pixels 10. The photoelectric converter 14 may include at least one of, for example, a photodiode, a phototransistor, a photogate, a pinned photodiode, an organic photodiode, a quantum dot, and a combination thereof, but is not limited thereto.

The first photoelectric converter 14A may be arranged adjacent or proximate a center side of the chip substrate 20 in the pixel 10. The term “center side of the chip substrate 20” may be a center line C (two dots-dashed line in the drawing) side that causes a left-right symmetry of the pixel array 110 illustrated in FIG. 1A. The second photoelectric converter 14B may be arranged on the outer periphery side of the chip substrate 20 in the pixel 10. In the photoelectric converter 14 that has the shape illustrated in FIG. 2A, the right sides of the drawings of the green color pixel 10G and the blue color pixel 10B may be referred to as the first photoelectric converters 14A, and the left sides of the drawings of the green color pixel 10G and the blue color pixel 10B may be referred to as the second photoelectric converters 14B.

The first separation wall 15 may include a deep trench isolation (DTI). Referring to FIGS. 1B and 2A, the first separation wall 15 may be formed to surround the photoelectric converter 14 of the pixel 10. As a result, each photoelectric converter 14 of the pixel 10 may be separated from other pixels 10 adjacent to each other.

The second separation wall 16 may include the DTI. Referring to FIG. 2A, the second separation wall 16 may partition the photoelectric converter 14 in the pixel 10 into the first photoelectric converter 14A and the second photoelectric converter 14B. Referring to FIGS. 2A and 2B, the second separation wall 16 may include a first portion 16A arranged at a generally central portion of a pixel pitch P, and a second portion 16B arranged adjacent to the first portion 16A in the Y-axis direction with respect to the first portion 16A as the center. In other words, the second separation wall 16 may be formed by arranging the first portion 16A between two second portions 16B.

The solid-state imaging device 1 may be formed by optimizing the shape of the second separation wall 16 formed between the pixels 10 for each pixel 10 as described below. Accordingly, the solid-state imaging device 1 may obtain optimal phase difference information due to increased phase difference detection precision of each pixel 10.

Referring to FIGS. 2A and 2B, the second separation wall 16 may be formed such that a vertical position (or level or end) of a first end portion 16Aa, which is a surface of the first portion 16A of the second separation wall 16 on which light is incident in the thickness direction (Z-axis direction) of the solid-state imaging device 1, is lower than a vertical position (or level or end) of the second end portion 16Ba, which is a surface the second portion 16B of the second separation wall 16 on which light is incident. According to some example embodiments, the second end portion 16Ba, which is a surface of the second portion 16B of the second separation wall 16 on which light is incident, may be in contact with a first surface 14a of the photoelectric converter 14, and the first end portion 16Aa, which is a surface of the first portion 16A of the second separation wall 16 on which light is incident, may be apart from of the first surface 14a of the photoelectric converter 14 without being in contact with the first surface 14a of the photoelectric converter 14.

According to some example embodiments, in the solid-state imaging device 1, a distance from the first surface 14a of the photoelectric converter 14 to the first end portion 16Aa of the first portion 16A of the second separation wall 16 may be greater than a distance from the first surface 14a of the photoelectric converter 14 to the second end portion 16Ba of the second separation wall 16.

Because the first portion 16A of the second separation wall 16 has the shape described above, the solid-state imaging device 1 may suppress or reduce the occurrence of cross-talk between the first photoelectric converter 14A and the second photoelectric converter 14B while suppressing or reducing the reflection of incident light (refer to IL in FIG. 3) toward the on-chip lens 11. Accordingly, the phase difference detection precision of the solid-state imaging device 1 may be improved.

In addition, many of the solid-state imaging devices according to a comparative example may be optimized based on the green color (G) pixels which have a large number of pixels in the solid-state imaging device according to specifications of an on-chip lens or a DTI structure. Thus, in a solid-state imaging device according to the comparative example, the phase difference detection precision of the blue color (B) pixel or the red color (R) pixel may be deteriorated. On the other hand, the solid-state imaging device 1 according to some example embodiments may form the second separation wall 16 as an optimal shape according to a color or position for each pixel 10, and thus may perform the phase difference detection with high precision regardless of the arrangement or color of the pixels 10.

FIG. 3 is a diagram of conditions for defining a height of a first portion of a second separation wall 16, according to some example embodiments.

Conditions with respect to the height of the first portion 16A of the second separation wall 16 are described with reference to FIG. 3. FIG. 3 illustrates the path of the light, which is reflected from the first separation wall 15 among the light incident on the second photoelectric converter 14B with an incident angle 0, moving toward the first photoelectric converter 14A. The height of the first portion 16A of the second separation wall 16 may be such that the reflected light may be further reflected from the second separation wall 16 (the first portion 16A), proceed into the second photoelectric converter 14B, and be photoelectrically converted be obtained as correct information. On the other hand, when the height of the first portion 16A of the second separation wall 16 is relatively lower, the reflected light may not be reflected from the second separation wall 16 (the first portion 16A), may proceed or travel into the first photoelectric converter 14A, and may be photoelectrically converted, thereby causing cross-talk.

FIG. 3 illustrates a position of the first portion 16A for correctly reflecting light reflected from the first separation wall 15. As illustrated in FIG. 3, a distance L from the first surface 14a of the photoelectric converter 14 of each pixel 10 to the first end portion 16Aa of the first portion 16A may be Lₘₐₓ or less (L≤Lₘₐₓ) that is obtained by using Formulas 1 and 2 below.

$$tan θ = ( pixel pitch / 2 ) / {L}_{max} / 2 \qquad Formula 1 )$$

$${L}_{max} = ( pixel pitch ) / tan θ \qquad Formula 2 )$$

In Formulas 1 and 2, the incident angle θ illustrated in the lower drawing of FIG. 3 may be the incident angle of a main light line incident on the second photoelectric converter 14B. The pixel pitch P may be a distance in a width direction (X-axis direction) of the photoelectric converter 14 surrounded by the first separation wall 15 in each pixel 10.

Referring to FIG. 2B again, the second separation wall 16 may include a concave groove portion 16C formed from the first surface 14a of the photoelectric converter 14 toward the first end portion 16Aa of the first portion 16A.

The groove portion 16C may be formed by etching a Si substrate on which the photoelectric converter 14 is formed from a side of a second surface 14b of the photoelectric converter 14 so that the vertical position of the first end portion 16Aa of the second separation wall 16 becomes the distance L for each pixel 10 obtained in Formulas 1 and 2 described above. In other words, the groove portion 16C may be a portion remaining without being etched, and may include a material for forming the photoelectric converter 14. In addition, a depth of the groove portion 16C may correspond to the length (L in FIG. 3) between the first surface 14a of the photoelectric converter 14 and the first end portion 16Aa of the first portion 16A of the second separation wall 16. According to some example embodiments, the groove portion 16C may be formed between the first photoelectric converter 14A and the second photoelectric converter 14B, and may include the same material as the photoelectric converter 14.

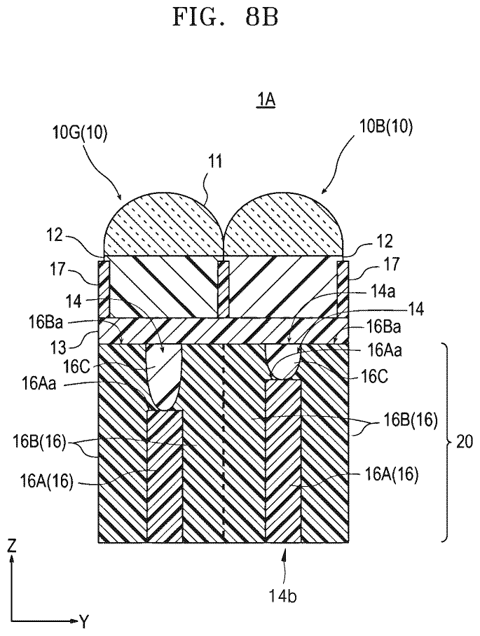

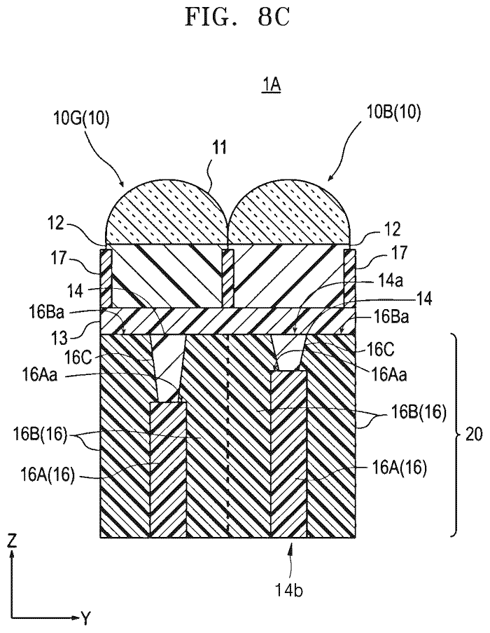

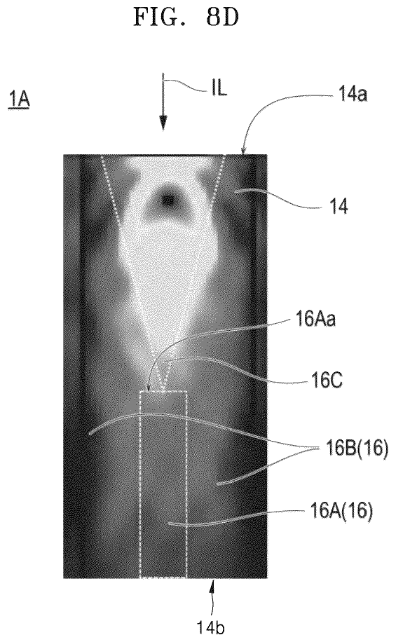

Referring to FIG. 2B again, the groove portion 16C may have a rectangular cross-section when viewed from a cross-section of the first portion 16A and the second portion 16B (a surface taken along line B-B). However, the shape of the cross-section of the groove portion 16C may not be limited to a rectangular shape, and may have any desired shape (and size) as per application and/or design, for example, as described with reference to FIGS. 8A through 8C below.

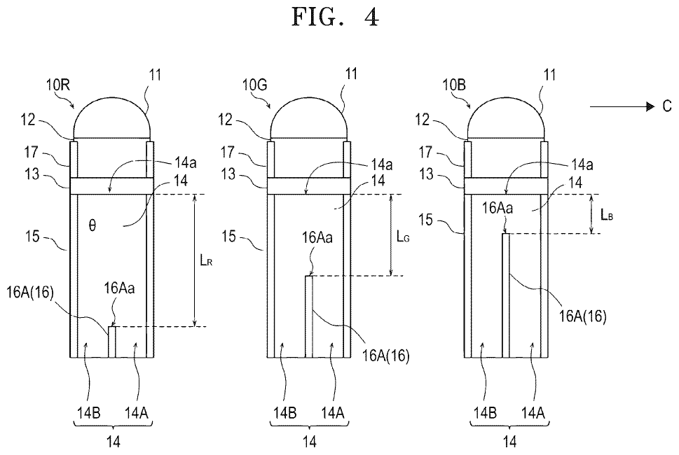

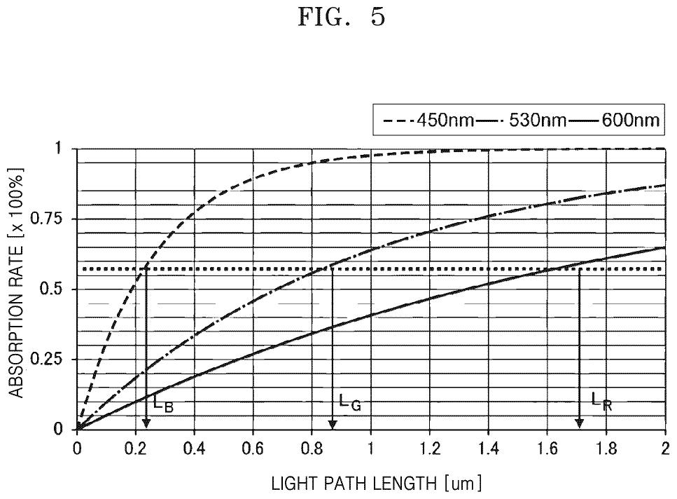

FIG. 4 is a diagram of relationships between a first distance (L_{R}) of a red color pixel, a second distance (L_{G}) of a green color pixel, and a third distance (L_{B}) of a blue color pixel, according to some example embodiments.

Referring to FIG. 4, in the solid-state imaging device 1, the distance between the first end portion 16Aa of the first portion 16A of the red color pixel 10R and the first surface 14a of the photoelectric converter 14 may be referred to as “the first distance L_{R}”. In the solid-state imaging device 1, the distance between the first end portion 16Aa of the first portion 16A of the green color pixel 10G and the first surface 14a of the photoelectric converter 14 may be referred to as “the second distance L_{G}”. In the solid-state imaging device 1, the distance between the first end portion 16Aa of the first portion 16A of the blue color pixel 10B and the first surface 14a of the photoelectric converter 14 may be referred to as “the third distance L_{B}”. At least one of the first distance L_{R}, the second distance L_{G}, and the third distance L_{B} is different from the other distances given the light path length for each color. According to some example embodiments, the first distance L_{R}, the second distance L_{G}, and the third distance L_{B} may be varied according to the arrangement position or color of the pixels, and may thus not be limited to any particular distances.

Referring to FIG. 4, when the material for forming the photoelectric converter 14 is Si, the solid-state imaging device 1 may be formed such that the first distance L_{R} of the red color pixel 10R, the second distance L_{G} of the green color pixel 10G, and the third distance L_{B} of the blue color pixel 10B satisfy the relationship L_{R}≥L_{G}≥L_{B}.

The absorption amount of light by the photoelectric converter 14 may be based on the Beer-Lambert Law, and may be proportional to a wavelength of the light path length required to absorb a certain amount of light. Accordingly, when the solid-state imaging device 1 suppresses or reduces or limits the reflection below a certain or given level, it may be desirable to form the solid-state imaging device 1 such that the first distance L_{R} of the red color pixel 10R, the second distance L_{G} of the green color pixel 10G, and the third distance L_{B} of the blue color pixel 10B satisfy the relationship described above. Thus, the vertical position of the first end portion 16Aa of the second separation wall 16 of the red color pixel 10R, the vertical position of the first end portion 16Aa of the second separation wall 16 of the green color pixel 10G, and the vertical position of the first end portion 16Aa of the second separation wall 16 of the blue color pixel 10B may gradually increase in this order in the thickness direction of the chip substrate 20. According to some example embodiments, the vertical position of the first end portion 16Aa of the second separation wall 16 of the blue color pixel 10B may be the highest. Accordingly, according to some example embodiments, the vertical positions of the first end portions 16Aa may be different depending on the colors of the color filter 12, and thus the depths of the groove portions 16C may be different.

FIG. 4 illustrates the first distance L_{R}, the second distance L_{G}, and the third distance L_{B} of the solid-state imaging device 1, according to some example embodiments. For the purposes of discussion, it is assumed that in the solid-state imaging device 1, about 30% of the light having reached the second separation wall 16 is reflected upward (to the side of the first surface 14a). Under this assumption, the first portion 16A of the second separation wall 16 may be arranged at a position where the absorption rate of the light in the solid-state imaging device 1 is about 60% of the light path length. Firstly, about 60% of the incident light IL may be absorbed by the photoelectric converter 14 before reaching the first portion 16A. About 30% of the remaining about 40% of the incident light IL, for example, about 12% of the total amount of the incident light IL, may be reflected toward the first surface 14a, and about 70% of the remaining about 40% of the incident light IL, for example, about 28% of the total amount of the incident light IL, may proceed in the direction of the second surface 14b and be totally absorbed. In addition, about 60% of the about 12% of the total reflected amount of the incident light IL, for example, about 7.2% of the total amount of the incident light IL, may be absorbed before exiting the photoelectric converter 14 (the first surface 14a). Thus, according to some example embodiments, a total light absorption rate of about 95.2% (about 60%+about 28%+about 7.2%) may be obtained.

FIG. 5 is a graph of an example of an absorption rate of the incident light IL with respect to a light path length in the photoelectric converter 14 including Si, according to some example embodiments.

FIG. 5 illustrates an example of an absorption rate of the incident light IL with respect to a light path length in the photoelectric converter 14 including Si, according to some example embodiments. In the graph of FIG. 5, the horizontal axis may represent a light path length, and the vertical axis may represent an absorption rate. For example, when a wavelength of the blue color light is about 450 nm, that of the green color light is about 530 nm, and that of the red color light is about 600 nm, when the first portion 16A of the second separation wall 16 is formed by forming the first distance L_{R} at 1.75 μm (or about 1.75 μm), the second distance L_{G} at 0.90 μm (or about 0.90 μm), and the third distance L_{B} at 0.25 μm (or about 0.25 μm), the incident light IL may realize the light absorption rate of 95% (or about 95%) or more.

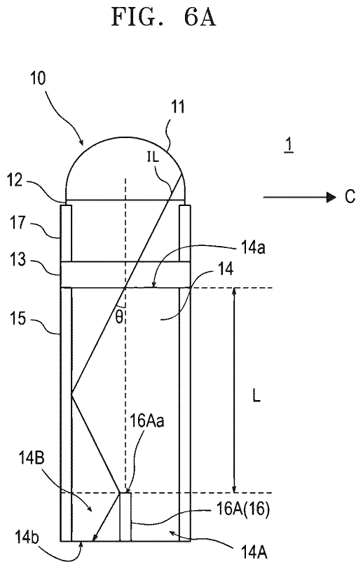

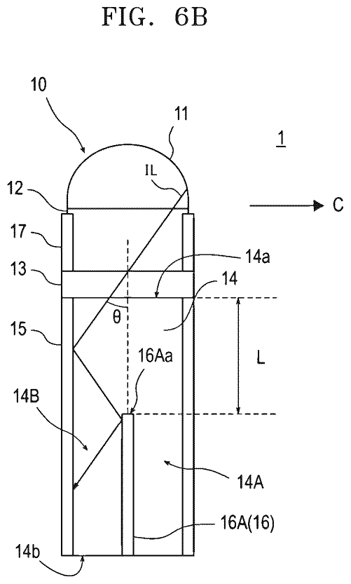

FIG. 6A is a schematic cross-sectional view of the pixel 10 arranged on the center side of the solid-state imaging device 1, according to some example embodiments. FIG. 6B is a schematic cross-sectional view of the pixel 10 arranged on the outer periphery side of the solid-state imaging device 1, according to some example embodiments.

FIG. 6A illustrates the pixel 10 arranged near the center of the pixel array 110 of the solid-state imaging device 1. FIG. 6B illustrates the pixel 10 arranged on the outer periphery side of the pixel array 110 of the solid-state imaging device 1.

In respective embodiments of FIGS. 6A and 6B, the distances L between the first end portion 16Aa of the first portion 16A of the second separation wall 16 of the solid-state imaging device 1 and the first surface 14a of the photoelectric converter 14 may be different from each other. According to some example embodiments, the solid-state imaging device 1 may be formed such that the distance L is shortened as the arrangement position of the pixel 10 moves away from the center of the pixel array 110 to the outer periphery side. According to some example embodiments, in the solid-state imaging device 1, the incident angle θ of the incident light IL incident on each pixel 10 may have a tendency to increase as the incident angle θ moves away from the center of the pixel array 110 toward the outer periphery of the pixel array 110. Thus, the solid-state imaging device 1 may receive the incident light IL from each pixel 10 by adjusting the distance L according to the arrangement position of the pixel 10.

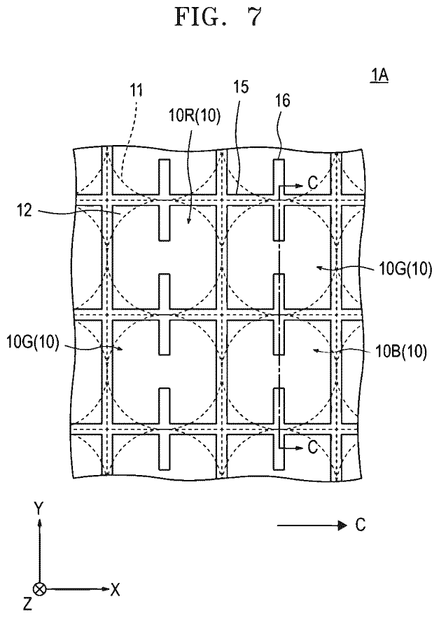

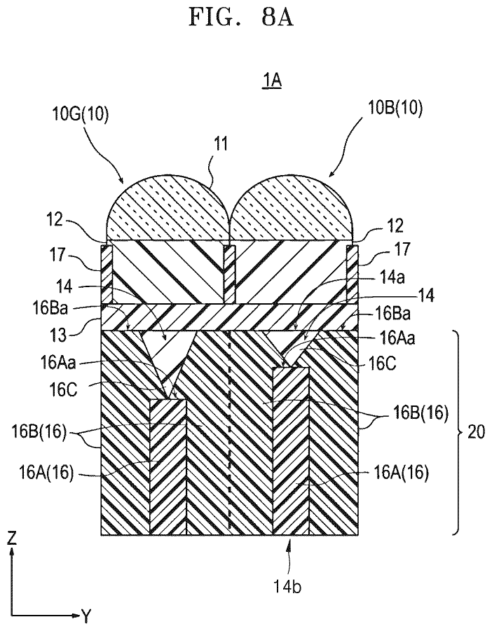

FIGS. 7-15 illustrate solid-state imaging devices that may be same as or similar in some respects to the solid-state imaging device 1 of FIG. 1A-2B, and therefore may be best understood with reference thereto where like numerals indicate like elements not described again in detail. In addition, the solid-state imaging devices of FIGS. 7-15 may also be implemented using different components among the components illustrated in each different embodiment and combining other components with other forms of components without departing from the scope of disclosure.

FIG. 7 is an enlarged cross-sectional view of a portion of the solid-state imaging device 1A taken in the horizontal direction, and FIGS. 8A, 8B, and 8C are examples of schematic cross-sectional views of the solid-state imaging device 1A taken along line C-C illustrated in FIG. 7.

Referring to FIGS. 8A and 8B, the solid-state imaging device 1A may include the groove portion 16C having a shape different from that of the groove portion 16C illustrated in FIG. 2B. The cross-sectional shape of the groove portion 16C may be appropriately selected according to the color of the pixel 10 or the arrangement position of the pixel 10 in the pixel array 110.

Referring to FIG. 8A, the groove portion 16C of the solid-state imaging device 1A may have a V-shaped cross-sectional shape including an end thereof narrowing (or tapering) from the first surface 14a of the photoelectric converter 14 toward the first end portion 16Aa of the first portion 16A, in the cross-section of the first portion 16A and the second portion 16B.

Referring to FIG. 8B, the groove portion 16C of the solid-state imaging device 1A may have a half-elliptical cross-sectional shape with an extending long radius from the first surface 14a of the photoelectric converter 14 toward the first end portion 16Aa of the first portion 16A, in the cross-section of the first portion 16A and the second portion 16B.

Referring to FIG. 8C, the groove portion 16C of the solid-state imaging device 1A may be formed to have an inverted trapezoid cross-section shape narrowing from the first surface 14a of the photoelectric converter 14 toward the first end portion 16Aa of the first portion 16A, in the cross-section of the first portion 16A and the second portion 16B.

FIG. 8D illustrates an example of the absorption distribution of the incident light IL of the pixel 10 in the solid-state imaging device 1A illustrated in FIG. 8A. Referring to FIG. 8D, the absorption region of the solid-state imaging device 1A may include an absorption region which is gradually narrowed from the first surface 14a of the photoelectric converter 14 toward the first end portion 16Aa of the first portion 16A. Accordingly, the shape of the groove portion 16C of the solid-state imaging device 1A may be changed to permit the absorption of the incident light IL according to the absorption distribution of the incident light IL, as illustrated in FIGS. 8A through 8C.

In the solid-state imaging device 1A, the cross-sectional shape of the groove portion 16C may be formed in a different V-shape, a different half-elliptical shape, or a different inverted trapezoidal shape according to the color of the pixel 10 or the arrangement position of the pixel 10 in the pixel array 110. As a result, the solid-state imaging device 1A may have a reduced gap in the phase difference detection precision for each pixel 10, by changing the shape of the groove portion 16C according to the absorption distribution of the incident light IL without interfering with the absorption of the incident light IL. Accordingly, the solid-state imaging device 1A may have an improved phase difference detection precision.

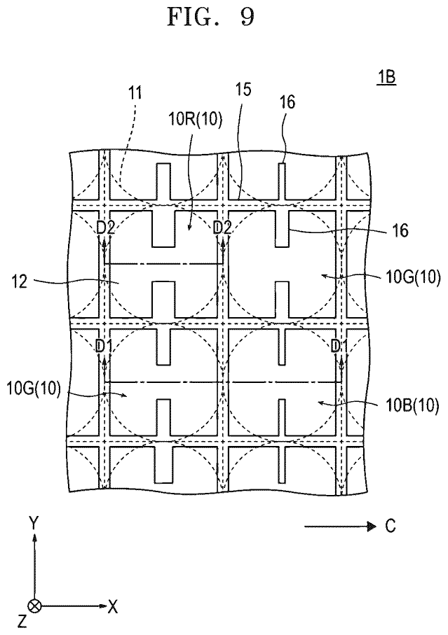

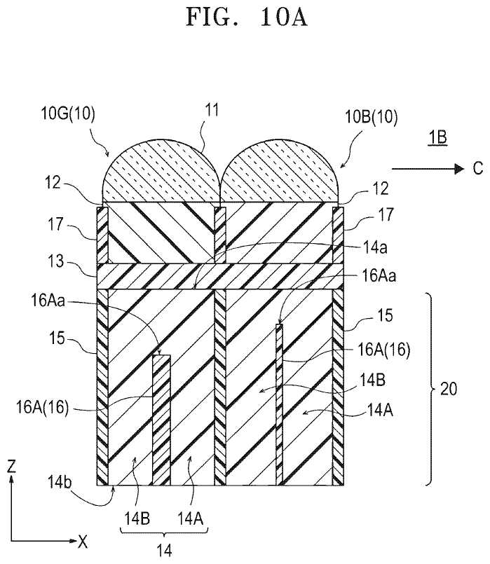

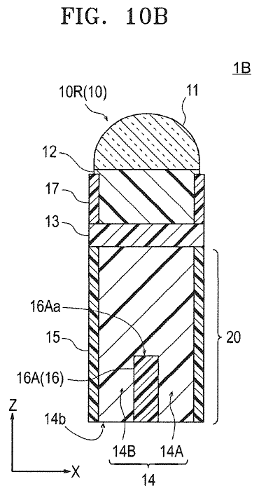

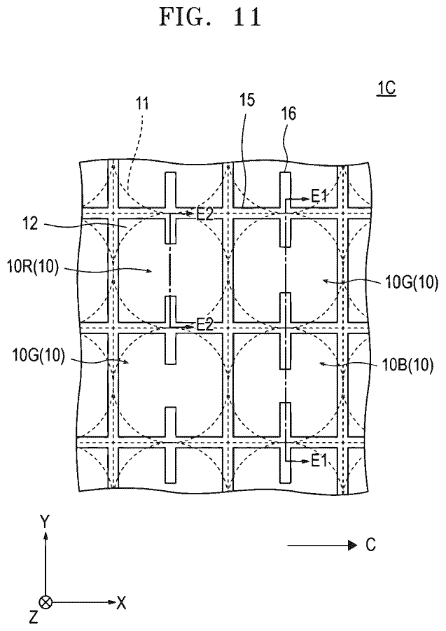

FIG. 9 is an enlarged cross-sectional view of a portion of the solid-state imaging device 1B taken in the horizontal direction, FIG. 10A is a cross-sectional view of the green color pixel 10G and the blue color pixel 10B taken along line D1-D1 in FIG. 9, and FIG. 10B is a cross-sectional view of the red color pixel 10R taken along line D2-D2 in FIG. 9.

Referring to FIGS. 10A and 10B, in the solid-state imaging device 1B, a layer thickness of the second separation wall 16 in the X-axis direction may be configured differently in at least some pixels 10, when viewed in a cross-section taken on an X-Z plane. The layer thickness of the second separation wall 16 in the X-axis direction may be determined according to the specification of the pixel 10, such as the color of the pixel 10 and the arrangement position of the pixel 10 in the pixel array 110. Referring to FIGS. 10A and 10B, in the solid-state imaging device 1B, the layer thickness of the second separation wall 16 in the X-axis direction may be reduced in the order of the red color pixel 10R, the green color pixel 10G, and the blue color pixel 10B. In the solid-state imaging device 1B, the length in the width direction, for example, the length in the X-axis direction, may be appropriately set in a state where the height of the first portion 16A is adjusted for each pixel 10. As a result, the solid-state imaging device 1B may improve the phase difference detection precision while reducing the gap in the phase difference detection precision for each pixel 10.

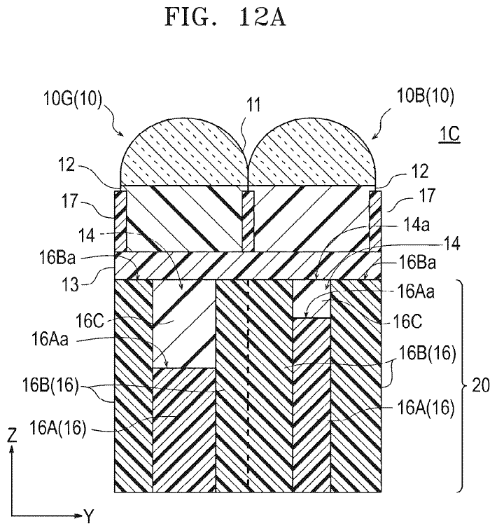

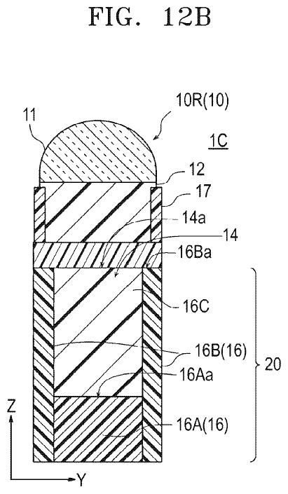

FIG. 11 is an enlarged cross-sectional view of a portion of the solid-state imaging device 1C taken in the horizontal direction, FIG. 12A is a cross-sectional view of the green color pixel 10G and the blue color pixel 10B taken along line E1-E1 in FIG. 11, and FIG. 12B is a cross-sectional view of the red color pixel 10R taken along line E2-E2 in FIG. 11.

In the solid-state imaging device 1C, a width of the groove portion 16C of the second separation wall 16 in the Y-axis direction may be configured differently from at least some pixels 10, when viewed in a cross-section of the first portion 16A and the second portion 16B. The width of the groove portion 16C in the Y-axis direction may be determined according to specifications of the pixel 10, such as the color of the pixel 10 and the arrangement position of the pixel 10 in the pixel array 110. Referring to FIGS. 12A and 12B, in the solid-state imaging device 1C, the width of the groove portion 16C in the Y-axis direction may be reduced in the order of the red color pixel 10R, the green color pixel 10G, and the blue color pixel 10B (R>G>B). In the solid-state imaging device 1C, the width of the groove portion 16C in the Y-axis direction may be appropriately set in a state where the height of the first portion 16A is adjusted for each pixel 10. As a result, the solid-state imaging device 1C may improve the phase difference detection precision while reducing the gap in the phase difference detection precision for each pixel 10.

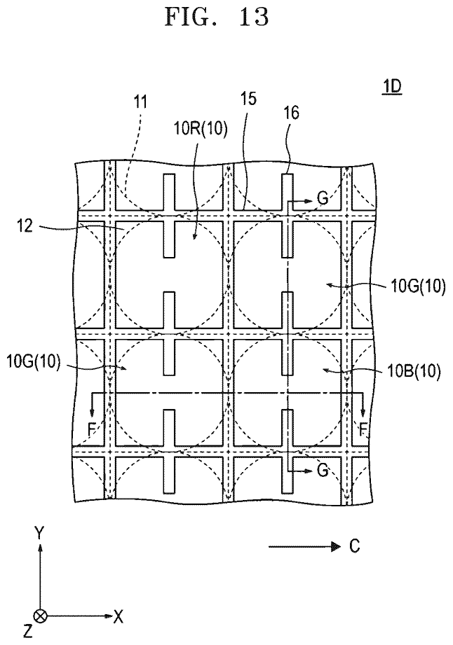

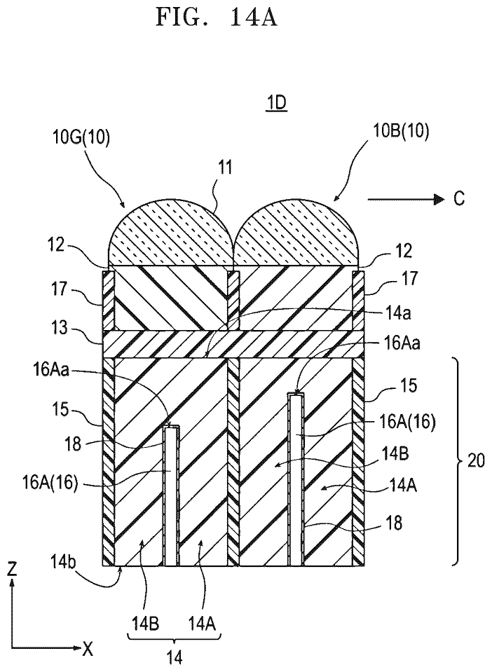

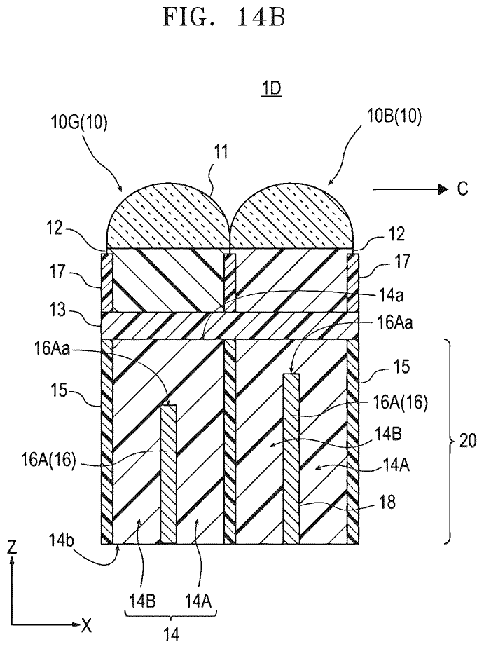

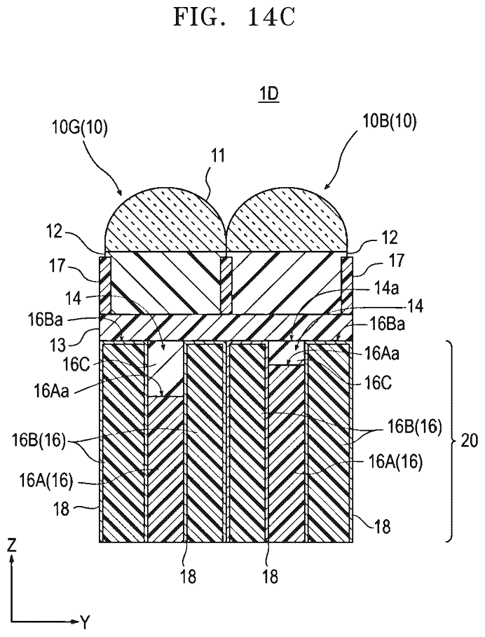

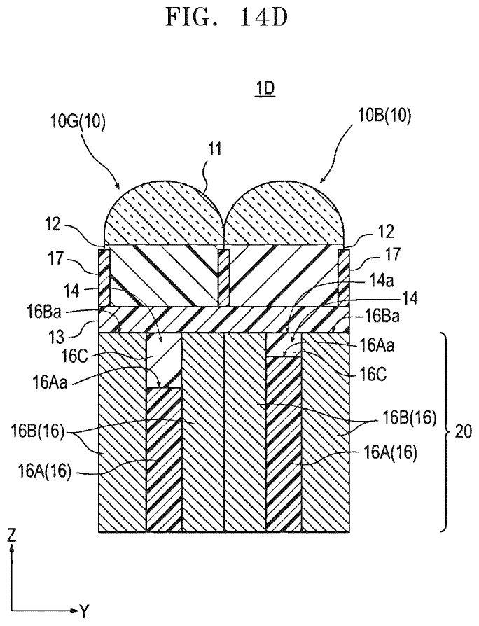

FIG. 13 is an enlarged cross-sectional view of a portion of the solid-state imaging device 1D taken in the horizontal direction, and FIGS. 14A and 14B are schematic cross-sectional views of the solid-state imaging device 1D taken along line F-F illustrated in FIG. 13. FIGS. 14C and 14D are schematic cross-sectional views of the solid-state imaging device 1D taken along the G-G line illustrated in FIG. 13.

The solid-state imaging device 1D may include at least one of the first portion 16A and the second portion 16B of the second separation wall 16 in a form including a dielectric material or in a form coated with a dielectric layer. The dielectric material or dielectric layer may include a material that does not absorb or may reflect (e.g., substantially) light with a wavelength of at least a visible range (about 380 nm or more and less than about 780 nm), and may include, for example, silicon oxide (SiO₂), silicon nitride (SiN), aluminum oxide (Al₂O₃), etc.

Referring to FIG. 14A, in the solid-state imaging device 1D, the outer periphery surface of the first portion 16A of the second separation wall 16 is coated with the dielectric layer 18. Referring to FIG. 14B, the solid-state imaging device 1D may include the first portion 16A of the second separation wall 16 including a dielectric material. Referring to FIG. 14C, in the solid-state imaging device 1D, the outer periphery surface of the second portion 16B of the second separation wall 16 is coated with the dielectric layer 18. Referring to FIG. 14D, in the solid-state imaging device 1D, the second portion 16B of the second separation wall 16 may include a dielectric material. The solid-state imaging device 1D may include one or more of the shapes illustrated in FIGS. 14A through 14D.

The solid-state imaging device 1D may improve the phase difference detection precision by forming the first portion 16A and/or the second portion 16B of the second separation wall 16 with a dielectric material or coating the first portion 16A and/or the second portion 16B with a dielectric layer to suppress or reduce or the absorption of the incident light IL.

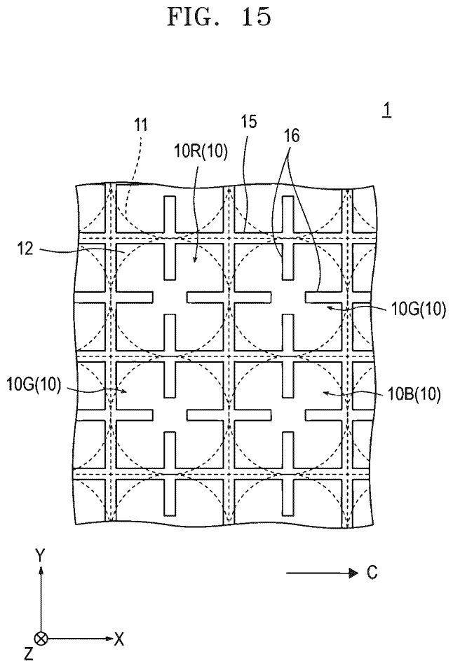

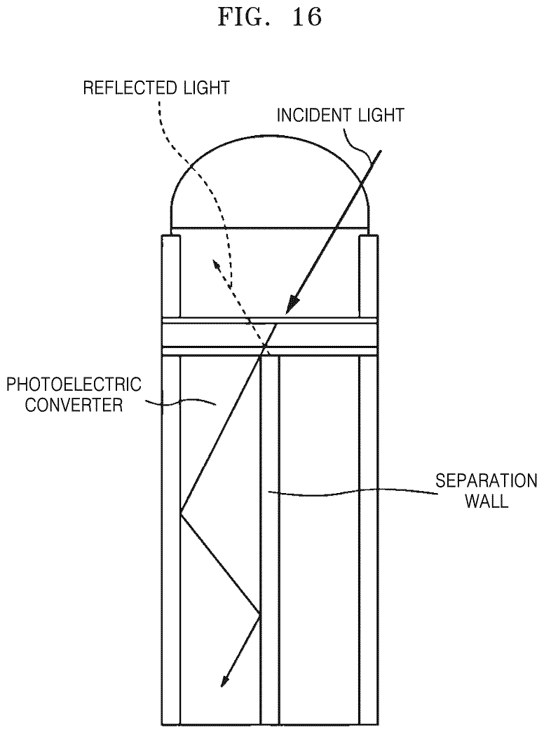

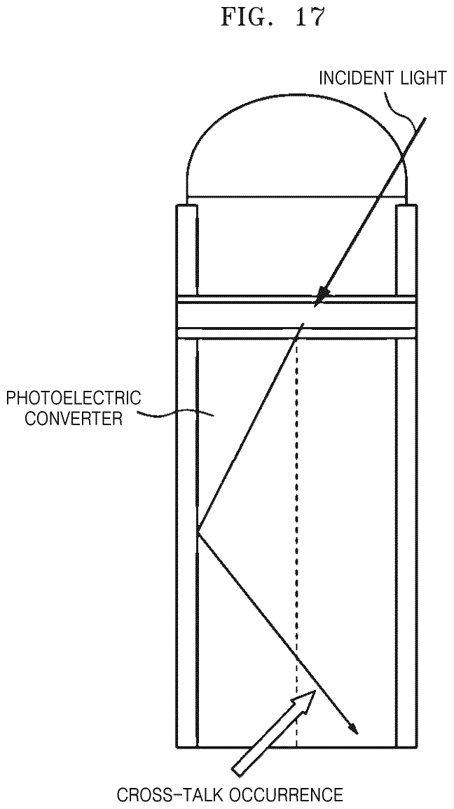

FIG. 15 is a partially enlarged cross-sectional view of a portion of the solid-state imaging device 1 in which the photoelectric converter 14 is partitioned into four portions on the second separation wall 16 in the horizontal direction, according to some example embodiments.

In the solid-state imaging device, according to some example embodiments discussed above, the photoelectric converter 14 may be partitioned by the second separation wall 16 in the pixel 10 into two partitions. However, the number of partitions of the photoelectric converter 14 in the pixel 10 are not limited to two. According to some example embodiments, the pixel 10 may include the photoelectric converter 14 that is divided by the first separation wall 15 into, for example, four partitions illustrated in FIG. 15.

As described above, in the solid-state imaging device 1 according to some example embodiments of the inventive concepts, the plurality of pixels 10 may be arranged in a two-dimensional array form on the chip substrate 20. Each pixel 10 may include a phase difference-detectable pixel including the first photoelectric converter 14A and the second photoelectric converter 14B. Each pixel 10 may include the first separation wall 15 surrounding the periphery of the photoelectric converter 14 and the second separation wall 16 formed between the first photoelectric converter 14A and the second photoelectric converter 14B. The second separation wall 16 may include the first portion 16A arranged approximately at the center of the pixel pitch P and the second portions 16B sandwiching the first portion 16A therebetween and adjacent to the first portion 16A. The vertical position or level of the first end portion 16Aa may be lower than the vertical position or level of the second end portion 16Ba. The first end portion 16Aa is the surface of the first portion 16A in the thickness direction of the solid-state imaging device 1 on which light is incident. The second end portion 16Ba is the surface of the second portion 16B in the thickness direction of the solid-state imaging device 1 on which light is incident.

The solid-state imaging device 1 (and the solid-state imaging devices 1A, 1B, 1C, and 1D, similarly), according to some example embodiments, may suppress, reduce, or limit cross-talk between photoelectric converters 14 partitioned in each pixel 10 and/or reflection occurring at the first end portion 16Aa of the first portion 16A of the second separation wall 16 (e.g., the end portion of the separation wall). As a result, the solid-state imaging device 1 (and the solid-state imaging devices 1A, 1B, 1C, and 1D, similarly), may improve the phase difference detection precision.

As described herein, any devices, systems, modules, portions, units, controllers, circuits, and/or portions thereof according to any of the example embodiments, and/or any portions thereof (including, without limitation, the control circuit 120, the vertical driving circuit 130, the horizontal driving circuit 140, the column signal processing circuit 150, any portion thereof, or the like) may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, systems, modules, portions, units, controllers, circuits, and/or portions thereof according to any of the example embodiments.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

While several embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

What is claimed is:

1. A solid-state imaging device comprising:
a two-dimensional pixel array including a plurality of pixels on a chip substrate,
wherein each pixel of the plurality of pixels comprises a photoelectric converter configured to detect a phase difference and including a first photoelectric converter and a second photoelectric converter,
wherein each pixel of the plurality of pixels comprises a first separation wall configured to surround a periphery of the photoelectric converter and a second separation wall between the first photoelectric converter and the second photoelectric converter,
wherein the second separation wall comprises a first portion in a center portion of a pixel pitch, and a second portion adjacent to the first portion,
wherein a vertical position of a first end portion of the first portion is lower than a vertical position of a second end portion of the second portion, and
wherein light is incident on the first end portion and the second end portion of the solid-state imaging device in a Z-axis direction.

2. The solid-state imaging device of claim 1,
wherein the second separation wall comprises a groove portion, the groove portion being concave from a first surface of the photoelectric converter toward the first end portion of the first portion, and
wherein the groove portion comprises a same material as the photoelectric converter.

3. The solid-state imaging device of claim 1,
wherein the first photoelectric converter is adjacent a center side of the chip substrate,
wherein the second photoelectric converter is on an outer periphery side of the chip substrate,
wherein a distance between the first end portion of the second separation wall and a first surface is equal to or less than pixel pitch/tan θ with respect to an incident angle θ of light incident on the second photoelectric converter, and
wherein the first surface is a surface of the photoelectric converter on which the light is incident.

4. The solid-state imaging device of claim 1,
wherein the plurality of pixels comprises a red color pixel, a green color pixel, and a blue color pixel, and
wherein at least one of (1) a first distance (L_{R}) between the first end portion of the first portion of the red color pixel and a first surface of the photoelectric converter,
(2) a second distance (L_{G}) between the first end portion of the first portion of the green color pixel and the first surface of the photoelectric converter, and
(3) a third distance (L_{B}) between the first end portion of the first portion of the blue color pixel and the first surface of the photoelectric converter is different from other of the first distance, the second distance, and the third distance.

5. The solid-state imaging device of claim 1,
wherein the plurality of pixels comprises a red color pixel, a green color pixel, and a blue color pixel, and
wherein (1) a first distance (L_{R}) between the first end portion of the first portion of the red color pixel and a first surface of the photoelectric converter, (2) a second distance (L_{G}) between the first end portion of the first portion of the green color pixel and the first surface of the photoelectric converter, and (3) a third distance (L_{B}) between the first end portion of the first portion of the blue color pixel and the first surface of the photoelectric converter satisfies a relationship of the first distance (L_{R})≥the second distance (L_{G})≥the third distance (L_{B}), wherein the photoelectric converter comprises silicon.

6. The solid-state imaging device of claim 2,
wherein a shape of the groove portion, when viewed in a cross-section of the first portion and the second portion, has any one of a rectangular shape, a V-shape tapered from the first surface of the photoelectric converter toward the first end portion, or a half-elliptical shape extending from the first surface of the photoelectric converter toward the first end portion.

7. The solid-state imaging device of claim 1,
wherein a width and/or a height of the second separation wall in a cross-section of the first portion is different in at least two pixels of the plurality of pixels.

8. The solid-state imaging device of claim 1,
wherein widths of the first portion of the second separation wall are different in a cross-section of the first portion and the second portion in at least two pixels of the plurality of pixels.

9. The solid-state imaging device of claim 1,
wherein at least one of the first portion or the second portion of the second separation wall comprises a dielectric material or is coated with the dielectric material.

10. The solid-state imaging device of claim 1,
wherein a distance between the first end portion of the first portion and a first surface of the photoelectric converter of the plurality of pixels decreases from a center of the two-dimensional pixel array toward an outer periphery of the two-dimensional pixel array.

11. A solid-state imaging device comprising:
a two-dimensional array of a plurality of pixels,
wherein each pixel of the plurality of pixels comprises a separation wall configured to separate a photoelectric converter included in the pixel,
wherein the separation wall comprises a first portion in a center portion of a pixel pitch and two second portions on both sides of the first portion in a second direction,
wherein end portions of the two second portions are configured to contact a first surface and an end portion of the first portion is apart from the first surface, and wherein the first surface is a surface of the photoelectric converter on which light is incident.

12. The solid-state imaging device of claim 11,
wherein the plurality of pixels comprise a first pixel and a second pixel adjacent to each other, and
wherein a height of the first portion of the separation wall included in the first pixel is different from a height of the first portion of the separation wall included in the second pixel.

13. The solid-state imaging device of claim 11,
wherein the plurality of pixels comprise a first pixel and a second pixel adjacent to each other,
wherein a length of the first portion of the separation wall included in the first pixel in a first direction is different from a length of the first portion of the separation wall included in the second pixel in the first direction, and
wherein the first direction is perpendicular to the second direction.

14. The solid-state imaging device of claim 11,
wherein the plurality of pixels comprise a first pixel and a second pixel adjacent to each other, and
wherein a length of the first portion of the separation wall included in the first pixel in the second direction is different from a height of the first portion of the separation wall included in the second pixel in the second direction.

15. A solid-state imaging device comprising:
a plurality of pixels on a chip substrate,
wherein each pixel of the plurality of pixels comprises:
a first photoelectric converter and a second photoelectric converter inside the chip substrate;
a separation wall between the first photoelectric converter and the second photoelectric converter;
a color filter on the first photoelectric converter and the second photoelectric converter; and
an on-chip lens on the color filter,
wherein the separation wall further comprises a groove portion between the first photoelectric converter and the second photoelectric converter, and
wherein the groove portion comprises a same material as the first photoelectric converter and the second photoelectric converter.

16. The solid-state imaging device of claim 15, wherein depths of the groove portions of at least two pixels of the plurality of pixels are different according to colors of color filters of the at least two pixels.

17. The solid-state imaging device of claim 15, wherein a depth of the groove portion is based on an angle of incident light incident through the on-chip lens and a pixel pitch of the pixel.

18. The solid-state imaging device of claim 15,
wherein a width of the groove portion decreases from a first surface toward a second surface opposite to the first surface, and
wherein the first surface is a surface of the first photoelectric converter and the second photoelectric converter on which light is incident.

19. The solid-state imaging device of claim 15, wherein widths of the groove portions of at least two pixels of the plurality of pixels in a first direction are different according to colors of color filters of the at least two pixels.

20. The solid-state imaging device of claim 15, wherein widths of the groove portions of at least two pixels of the plurality of pixels in a second direction are different according to colors of color filters of the at least two pixels.
